(19) United States
(12) Patent Application Publication
(10) Pub. No.: US 2021/0296384 A1
(43) Pub. Date: Sep. 23, 2021

(54) SEMICONDUCTOR DEVICE

(71) Applicant: SONY SEMICONDUCTOR SOLUTIONS CORPORATION, KANAGAWA (JP)

(72) Inventors: MASANAGA FUKASAWA, KANAGAWA (JP); KAN SHIMIZU, KANAGAWA (JP); TADAYUKI KIMURA, KANAGAWA (JP); TOSHIAKI SHIRAIWA, KANAGAWA (JP)

(21) Appl. No.: 17/250,664

(22) PCT Filed: Aug. 19, 2019
(86) PCT No.: PCT/JP2019/032267

§ 371 Date: Feb. 17, 2021

(30) Foreign Application Priority Data
Aug. 31, 2018 (JP) 2018-163376

(51) Int. Cl. H01L 27/146; H01L 27/22; H01L 43/02; H01L 43/08

(52) U.S. Cl. CPC H01L 27/14609; H01L 27/222; H01L 43/02; H01L 27/14634; H01L 27/1464; H01L 27/14618; H01L 27/14636; H01L 43/08

(57) ABSTRACT

To provide a semiconductor device having a structure suitable for higher integration. This semiconductor device serving as an embodiment of the present disclosure includes: a storage element; a first contact that is electrically coupled to this storage element; a second contact that is positioned on an opposite side to the first contact in a first direction; a protective film that surrounds the storage element in a first plane orthogonal to the first direction; and a first hydrogen block layer that surrounds the protective film in the first plane. The second contact is electrically coupled to the storage element.

### TECHNICAL FIELD

The present disclosure relates to a semiconductor device including a storage element.

### BACKGROUND ART

For a semiconductor integrated circuit including a CMOS (Complementary Metal Oxide Semiconductor) transistor, higher integration and higher operating speed thereof have been studied in the past. In recent years, from a viewpoint of lower power consumption, switching from a volatile memory to a non-volatile memory has been studied. For example, the development of MRAM (Magnetoresistive Random Access Memory) has been under way (see, for example, PTL 1).

### CITATION LIST

### Patent Literature

PTL 1: Japanese Unexamined Patent Application Publication No. 2015-65407

### SUMMARY OF THE INVENTION

Incidentally, still higher operational reliability is necessary for a semiconductor device including such a semiconductor integrated circuit. Accordingly, it is desirable to provide a semiconductor device having excellent operational reliability.

A semiconductor device serving as an embodiment of the present disclosure includes: a storage element; a first contact that is electrically coupled to the storage element; a second contact that is positioned on an opposite side to the first contact layer in a first direction; a protective film that surrounds the storage element in a first plane orthogonal to the first direction; and a first hydrogen block layer that surrounds the protective film in the first plane. The second contact is electrically coupled to the storage element.

In the semiconductor device serving as the embodiment of the present disclosure, the entry of hydrogen to the storage element is blocked.

### BRIEF DESCRIPTION OF DRAWING

FIG. 1 is a cross-sectional view of an overall configuration example of an imaging device according to a first embodiment of the present disclosure.

FIG. 2 is an enlarged cross-sectional view of a configuration example of a main portion of the imaging device illustrated in FIG. 1.

FIG. 3A is a cross-sectional view of a step of a method of forming the main portion of the imaging device illustrated in FIG. 1.

FIG. 3B is a cross-sectional view of a step subsequent to FIG. 3A.

FIG. 3C is a cross-sectional view of a step subsequent to FIG. 3B.

FIG. 3D is a cross-sectional view of a step subsequent to FIG. 3C.

FIG. 3E is a cross-sectional view of a step subsequent to FIG. 3D.

FIG. 4 is a cross-sectional view of a configuration example of a main portion of an imaging device serving as a first modification example of the present disclosure.

FIG. 5 is a cross-sectional view of a configuration example of a main portion of an imaging device serving as a second modification example of the present disclosure.

FIG. 6 is a cross-sectional view of a configuration example of a main portion of an imaging device serving as a third modification example of the present disclosure.

FIG. 7 is a cross-sectional view of a configuration example of a main portion of an imaging device serving as a fourth modification example of the present disclosure.

FIG. 8A is a cross-sectional view of a step of a method of forming the main portion of the imaging device serving as the third modification example illustrated in FIG. 6.

FIG. 8B is a cross-sectional view of a step subsequent to FIG. 8A.

FIG. 9 is a cross-sectional view of a configuration example of a main portion of an imaging device according to a second embodiment of the present disclosure.

FIG. 10A is a cross-sectional view of a step of a method of forming the main portion of the imaging device according to the second embodiment illustrated in FIG. 9.

FIG. 10B is a cross-sectional view of a step subsequent to FIG. 10A.

FIG. 10C is a cross-sectional view of a step subsequent to FIG. 10B.

FIG. 11 is a cross-sectional view of a configuration example of a main portion of an imaging device serving as a fifth modification example of the present disclosure.

FIG. 12A is a cross-sectional view of a step of a method of forming the main portion of the imaging device serving as the fifth modification example illustrated in FIG. 11.

FIG. 12B is a cross-sectional view of a step subsequent to FIG. 12A.

FIG. 13 is a cross-sectional view of a configuration example of a main portion of an imaging device serving as a sixth modification example of the present disclosure.

FIG. 14 is a cross-sectional view of a configuration example of a main portion of an imaging device serving as a seventh modification example of the present disclosure.

FIG. 15A is a cross-sectional view of a step of a method of forming the main portion of the imaging device serving as the seventh modification example illustrated in FIG. 14.

FIG. 15B is a cross-sectional view of a step subsequent to FIG. 15A.

FIG. 15C is a cross-sectional view of a step subsequent to FIG. 15B.

FIG. 16 is a schematic diagram illustrating an overall configuration example of an electronic apparatus according to a third embodiment of the present disclosure.

FIG. 17 is a block diagram depicting an example of schematic configuration of a vehicle control system.

FIG. 18 is a diagram of assistance in explaining an example of installation positions of an outside-vehicle information detecting section and an imaging section.

FIG. 19 is a view depicting an example of a schematic configuration of an endoscopic surgery system.

FIG. 20 is a block diagram depicting an example of a functional configuration of a camera head and a camera control unit (CCU).

FIG. 21 is a cross-sectional view of an overall configuration example of an imaging device serving as an eighth modification example of the present disclosure.

FIG. 22 is a cross-sectional view of an overall configuration example of an imaging device serving as a ninth modification example of the present disclosure.

### MODES FOR CARRYING OUT THE INVENTION

The following describes embodiments of the present disclosure in detail with reference to the drawings. It is to be noted that description is given in the following order.

1. First Embodiment (Example of imaging device in which end surfaces of storage element are surrounded by hydrogen block layer with insulating protective films interposed therebetween)

### 1-1. Basic Form

### 1-2. First Modification Example

### 1-3. Second Modification Example

### 1-4. Third Modification Example and Fourth Modification Example

2. Second Embodiment (Example of imaging device provided with hydrogen block layer that surrounds end surfaces of storage element and covers even upper contact)

### 2-1. Basic Form

### 2-2. Fifth Modification Example

### 2-3. Sixth Modification Example

### 2-4. Seventh Modification Example

### 3. Third Embodiment (Example of Application to Electronic Apparatus)

### 4. Example of Practical Application to Mobile Body

### 5. Example of Practical Application to Endoscopic Surgery System

### 6. Other Modification Examples

### 1. First Embodiment

### 1-1. Basic Form

### [Configuration of Imaging Device 1]

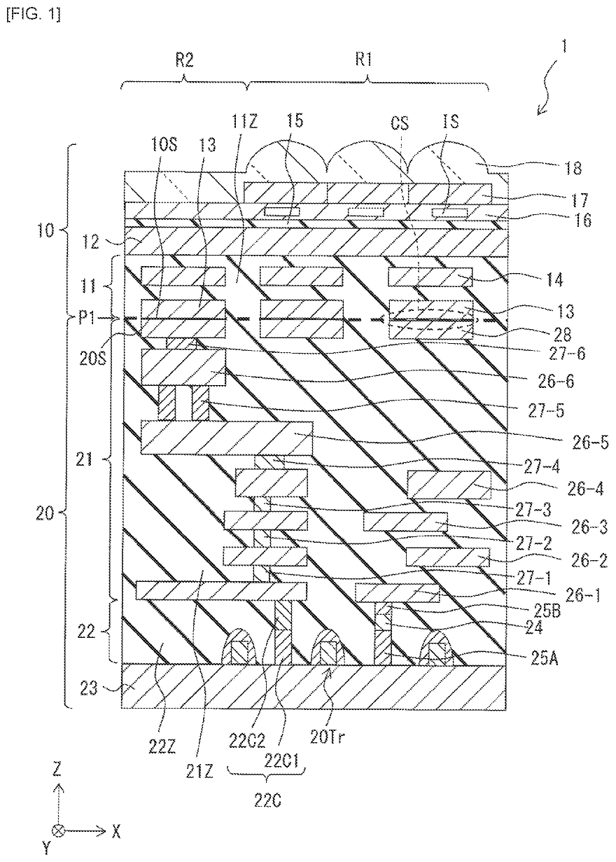

FIG. 1 is a schematic cross-sectional view of an overall configuration example of an imaging device 1 serving as a semiconductor device according to a first embodiment of the present disclosure.

As illustrated in FIG. 1, the imaging device 1 has a two-layer structure in which a sensor board 10 and a circuit board 20 are stacked. The sensor board 10 serves as a first board including a surface 10S. The circuit board 20 serves as a second board including a surface 20S. In the imaging device 1, the surface 10S and the surface 20S are joined together at a position P1. In the present embodiment, the stacked direction (also referred to as thickness direction) of the sensor board 10 and the circuit board 20 is defined as a Z axis direction and the plane in which the sensor board 10 and the circuit board 20 each extend is defined as an XY plane. This imaging device 1 is a so-called back-illuminated image sensor device.

### (Sensor Board 10)

The sensor board 10 includes a wiring layer 11 and a semiconductor layer 12. The wiring layer 11 includes a first wiring line. The wiring layer 11 and the semiconductor layer 12 are stacked in order from a position closer to the circuit board 20. The wiring layer 11 of the sensor board 10 includes an electrode 13 and a wiring line 14. The electrode 13 and the wiring line 14 are each formed by using, for example, a highly electrically conductive non-magnetic material such as Cu (copper) and embedded in an insulating layer 11Z including, for example, SiO₂ or the like. A portion of the electrode 13 is, however, exposed from the surface 10S. The semiconductor layer 12 is, for example, a Si (silicon) substrate.

The sensor board 10 further includes an insulating layer 15, a semiconductor layer 16, a color filter layer 17, and a microlens layer 18. The insulating layer 15, the semiconductor layer 16, the color filter layer 17, and the microlens layer 18 are stacked in order on the opposite side to the wiring layer 11 as viewed from the semiconductor layer 12. A solid-state imaging element IS including, for example, CMOS is embedded in the semiconductor layer 16. The insulating layer 15 also includes, for example, SiO₂ or the like.

### (Circuit Board 20)

The circuit board 20 includes a wiring layer 21, a storage element layer 22, and a semiconductor layer 23. The wiring layer 21, the storage element layer 22, and the semiconductor layer 23 are stacked in order from a position closer to the sensor board 10.

In the wiring layer 21, wiring lines 26-1 to 26-6, vias 27-1 to 27-6, and an electrode 28 are embedded in an insulating layer 21Z including, for example, SiO₂ or the like. A portion of the electrode 28 is, however, exposed from the surface 20S and joined to the electrode 13 exposed from the surface 10S to form a junction section CS. It is to be noted that the sensor board 10 includes a pixel region R1 and a peripheral region R2. The plurality of solid-state imaging elements IS is disposed in the pixel region R1. The peripheral region R2 surrounds the pixel region R1. It is sufficient if the junction section CS is formed at a position overlapping with the pixel region R1 in the stacked direction (Z axis direction) of the sensor board 10 and the circuit board 20. The junction section CS may also be, however, formed in the peripheral region R2. In addition, the electrode 28, the wiring lines 26-1 to 26-6, and the vias 27-1 to 27-6 are each formed by using, for example, a highly electrically conductive non-magnetic material such as Cu (copper). The electrode 13 and the electrode 28 form the junction section CS by using Cu—Cu junction in which, for example, the Cu included in the electrode 13 and the Cu included in the electrode 28 are directly joined together. This Cu—Cu junction secures the electrical conduction between the electrode 13 and the electrode 28. In addition, the wiring lines 26-1 to 26-6 and the vias 27-1 to 27-6 are alternately stacked in order from the storage element layer 22 side. It is to be noted that the following description sometimes refers to the wiring lines 26-1 to 26-6 collectively as wiring line(s) 26 and sometimes refers to the vias 27-1 to 27-6 collectively as via(s) 27.

The storage element layer 22 includes a transistor 20Tr, a storage element 24, a lower contact layer 25A, and an upper contact layer 25B. The transistor 20Tr is provided between the storage element 24 and the semiconductor layer 23. For example, the transistor 20Tr is provided near a surface of the semiconductor layer 23. The lower contact layer 25A is an electrically conductive layer that couples the storage element 24 and any one of the source electrode or the drain electrode of the transistor 20Tr. In addition, the upper contact layer 25B is an electrically conductive layer that couples the storage element 24 and the wiring line 26-1. Further, the other of the source electrode or the drain electrode of the transistor 20Tr is coupled to another wiring line 26-1 via a contact layer 22C1 and a contact layer 22C2. These transistor 20Tr, storage element 24, lower contact layer 25A, upper contact layer 25B, and the like are embedded in an insulating layer 22Z.

### [Detailed Configuration of Components Near Storage Element 24]

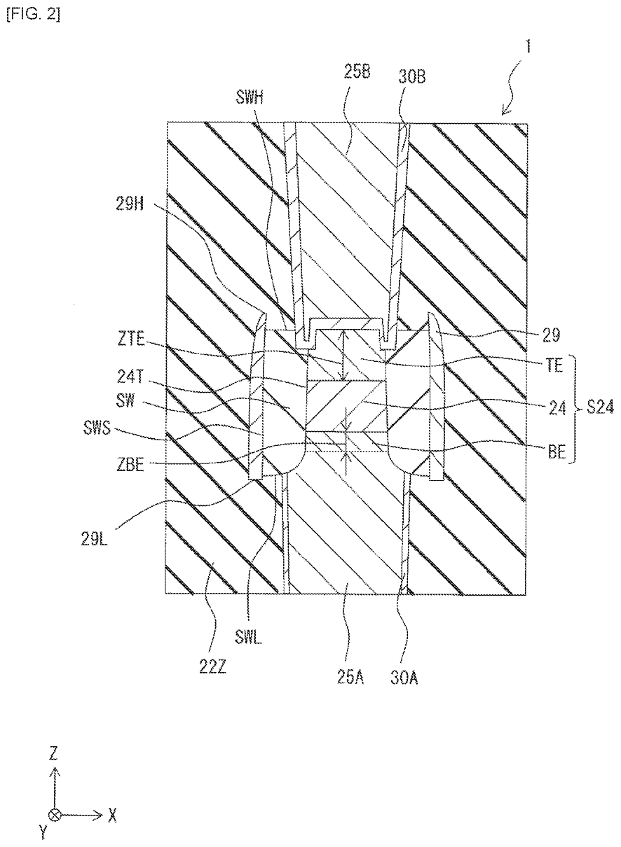

Next, with reference to FIG. 2, a configuration of components near the storage element 24 is described. FIG. 2 is a detailed enlarged cross-sectional view of components near the storage element 24 illustrated in FIG. 1.

As illustrated in FIG. 2, the circuit board 20 is provided with an insulating side wall section SW and a hydrogen block layer 29 near the storage element 24. The insulating side wall section SW serves as a protective film. The hydrogen block layer 29 prevents H₂ (hydrogen gas) or the like from passing therethrough. The side wall section SW covers end surfaces 24T of the storage element 24 to surround the end surfaces 24T in the XY plane. The hydrogen block layer 29 further covers at least a portion of an outer peripheral surface SWS of the side wall section SW. It is sufficient if the hydrogen block layer 29 covers the entire outer peripheral surface SWS of the side wall section SW to surround the side wall section SW in the XY plane with no gap. In addition, it is sufficient if the side wall section SW is provided between the position of a lower edge 29L of the hydrogen block layer 29 and the position of an upper edge 29H of the hydrogen block layer 29 in the thickness direction (Z axis direction). More specifically, a lower edge SWL of the side wall section SW is positioned above the position of the lower edge 29L. In other words, the lower edge SWL of the side wall section SW is positioned on the upper contact layer 25B side. The lower edge SWL of the side wall section SW is positioned below the position of the upper edge 29H. In other words, the lower edge SWL of the side wall section SW is positioned on the lower contact layer 25A side.

The hydrogen block layer 29 is a thin layer that is formed, for example, in a sputtering method. The hydrogen block layer 29 includes, for example, a metal material such as Ti (titanium) that occludes hydrogen. It is sufficient if the hydrogen block layer 29 blocks the passage of O₂ (oxygen gas), H₂O (water), a hydrogen radical, and the like in addition to a hydrogen gas. A hydrogen gas, an oxygen gas, water, and a hydrogen radical are all degradation causing substances that may cause the storage element 24 to have performance degradation. Such a degradation causing substance is sometimes generated in a step of manufacturing the imaging device 1. Such a degradation causing substance is sometimes generated especially when the surface 10S and the surface 20S are joined together or when the wiring line 26, the via 27, and the like in the wiring layer 21 are formed. The presence of the hydrogen block layer 29 makes it difficult for the above-described degradation causing substance to reach the storage element 24.

The storage element 24 has, for example, the stacked structure of a magnetic tunnel junction (MTJ) element or the like including a plurality of magnetic layers stacked, for example, in the Z axis direction. The storage element 24 is supplied with a sense current in the Z axis direction, thereby writing information and reading the information. The storage element 24 is sandwiched between the lower contact layer 25A and the upper contact layer 25B in the stacked direction (Z axis direction). The circuit board 20 further includes a lower electrode BE serving as a first terminal and an upper electrode TE serving as a second terminal. The lower electrode BE is provided between the lower contact layer 25A and the storage element 24. The upper electrode TE is provided between the storage element 24 and the upper contact layer 25B. The lower electrode BE, the storage element 24, and the upper electrode TE are included in a stack S24. The lower electrode BE and the upper electrode TE may each include, for example, a highly electrically conductive material including one or more of Ti, TiN (titanium nitride), Ta (tantalum), TaN (tantalum nitride), W (tungsten), Cu, and Al (aluminum). The lower electrode BE and the upper electrode TE are not limited to a single-layer structure, but may each have a stacked structure in which a plurality of electrically conductive layers is stacked. Further, it is desirable that thickness ZTE of the upper electrode TE be greater than thickness ZBE of the lower electrode BE. This is because it is more difficult for the above-described degradation causing substance to reach the storage element 24.

The region around the lower contact layer 25A is covered with a barrier layer 30A. Similarly, the region around the upper contact layer 25B is covered with a barrier layer 30B. The lower contact layer 25A and the upper contact layer 25B each include a material including, for example, a highly electrically conductive material such as Cu, W, or Al as a main material. The barrier layers 30A and 30B each include a material including Ti alone, Ta (tantalum) alone, an alloy including at least one of the Ti and the Ta, or the like as a main material. In a case where the barrier layers 30A and 30B each include a material such as of Ti that occludes hydrogen, the barrier layers 30A and 30B each serve as a hydrogen block layer that blocks the passage of a hydrogen gas, O₂ (oxygen gas), H₂O (water), a hydrogen radical, and the like.

It is preferable that the storage element 24 be, for example, a spin transfer magnetization switching storage element (STT-MTJ; Spin Transfer Torque-Magnetic Tunnel Junctions) in which the orientation of magnetization of the storage layer described below is reversed by spin transfer to store information. The STT-MTJ is able to perform writing and reading at high speed. This is why the STT-MTJ is a promising non-volatile memory in place of a volatile memory.

The storage element 24 has a stacked structure in which, for example, an underlayer, a magnetization fixed layer, an insulating layer, a storage layer, and a cap layer are stacked in order from a component closer to the lower contact layer 25A. The storage element 24 stores information by changing the orientation of the magnetization of a storage layer having uniaxial anisotropy. Information “0” or “1” is defined by a relative angle (parallel or antiparallel) between the magnetization of the storage layer and the magnetization of the magnetization fixed layer.

The underlayer and the cap layer in the storage element 24 each include, for example, a metal film such as Ta or Ru or a stacked film thereof.

The magnetization fixed layer in the storage element 24 is a reference layer that is a reference for stored information (magnetization direction) in the storage layer. The magnetization fixed layer includes a ferromagnetic substance having a magnetic moment that has the direction of the magnetization fixed in the direction vertical to the film surface. The magnetization fixed layer includes, for example, Co—Fe—B.

It is not desirable to change the direction of the magnetization of the magnetization fixed layer in accordance with writing or reading, but the direction does not necessarily have to be fixed to a specific direction. This is because it is only necessary for the direction of the magnetization of the magnetization fixed layer to move less easily than the direction of the magnetization of the storage layer. For example, it is sufficient if the magnetization fixed layer has larger coercivity, a larger magnetic film thickness, or a larger magnetic damping constant than that of the storage layer. To fix the direction of the magnetization of the magnetization fixed layer, for example, it is sufficient if an antiferromagnetic substance such as PtMn or IrMn is provided in contact with the magnetization fixed layer. Alternatively, a magnetic substance in contact with such an antiferromagnetic substance may be magnetically linked to the magnetization fixed layer with a non-magnetic substance such as Ru interposed therebetween to indirectly fix the direction of the magnetization of the magnetization fixed layer.

An insulating layer in the storage element 24 is an intermediate layer serving as a tunnel barrier layer (tunnel insulating layer) and includes, for example, aluminum oxide or magnesium oxide (MgO). In particular, it is preferable that this insulating layer include magnesium oxide. This is because it is possible to increase a magnetoresistance change ratio (MR ratio) and increase spin transfer efficiency, thereby reducing current density for reversing the orientation of the magnetization of the storage layer.

The storage layer in the storage element 24 includes a ferromagnetic substance having a magnetic moment that freely changes the direction of the magnetization of the magnetization fixed layer in the direction vertical to the film surface. The storage layer includes, for example, Co—Fe—B.

### [Method of Forming Hydrogen Block Layer 29]

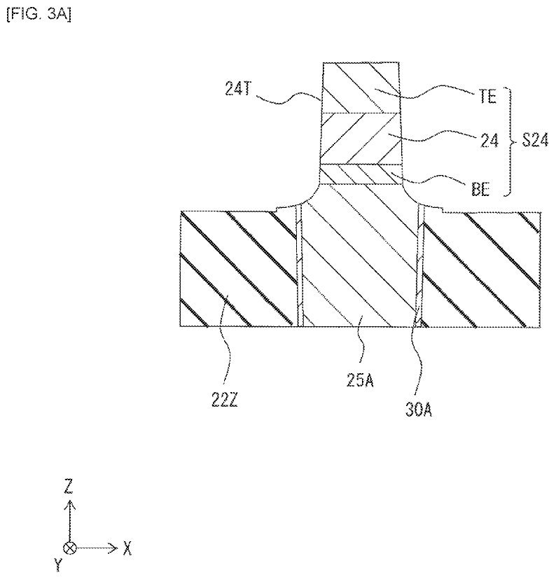

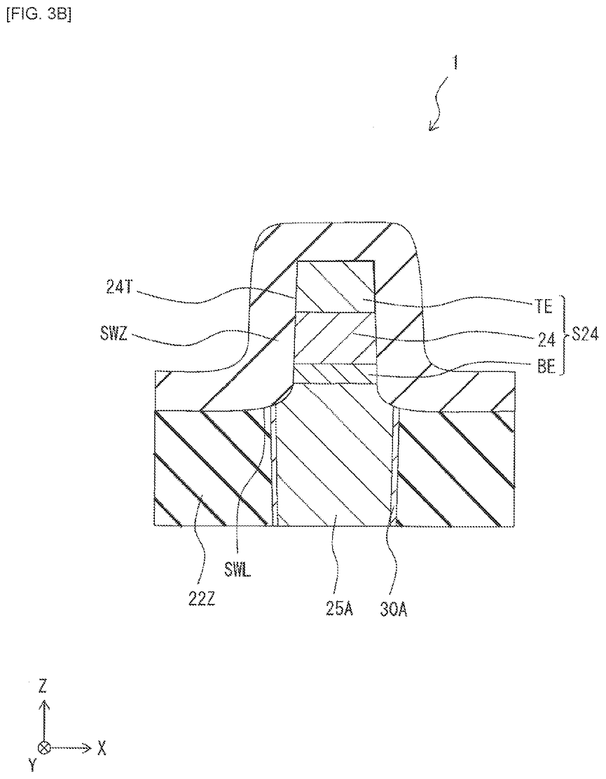

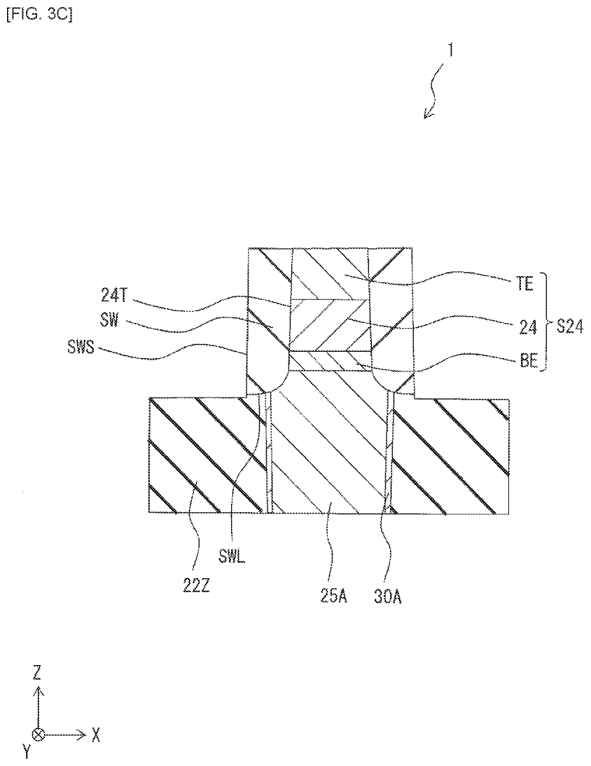

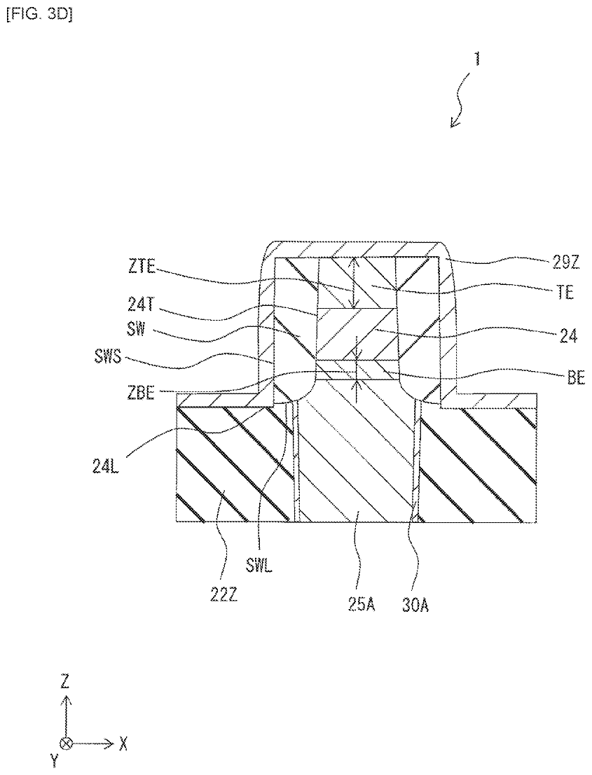

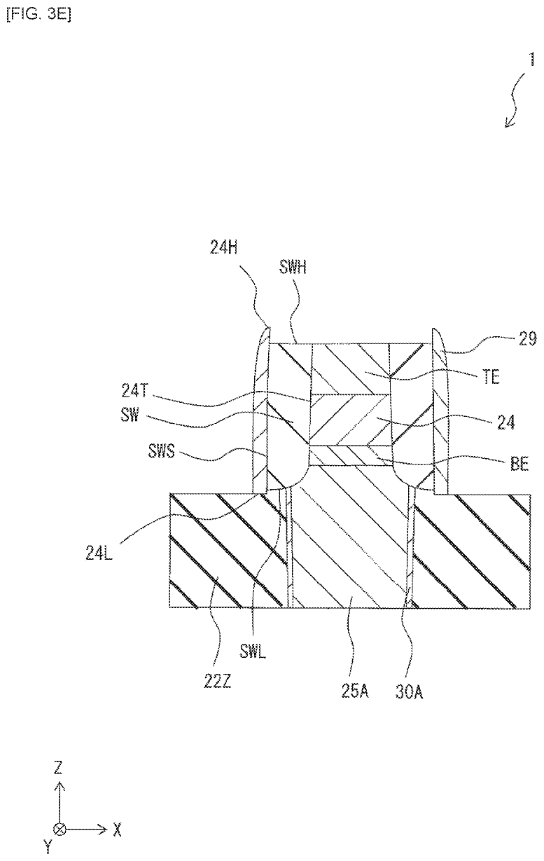

Next, with reference to FIGS. 3A to 3E in addition to FIG. 2, a method of forming the hydrogen block layer 29 is described. Each of FIGS. 3A to 3E is an enlarged cross-sectional view of a step of the method of forming the hydrogen block layer 29 provided near the storage element 24 illustrated in FIG. 1.

First, as illustrated in FIG. 3A, the stack S24 of the lower electrode BE, the storage element 24, and the upper electrode TE is selectively formed on the lower contact layer 25A embedded in the insulating layer 22Z including SiO2 or the like.

Next, as illustrated in FIG. 3B, a protective layer SWZ is formed by using SiN or the like to uniformly cover all the insulating layer 22Z, the lower contact layer 25A, and the stack S24.

Afterward, as illustrated in FIG. 3C, excluding only portions of the protective layer SWZ that cover the end surfaces 24T of the storage element 24, the other portions of the protective layer SWZ are selectively removed by dry etching. This forms the side wall section SW that covers the entire end surfaces 24T of the storage element 24.

Next, as illustrated in FIG. 3D, a metal layer 29Z is formed, for example, in a sputtering method by using Ti or the like to uniformly cover the insulating layer 22Z, the side wall section SW, and the upper electrode TE.

Finally, as illustrated in FIG. 3E, a portion of the metal layer 29Z is removed by etching back to expose the upper surface of the upper electrode TE. This forms the hydrogen block layer 29 that covers the outer peripheral surface SWS of the side wall section SW. It is to be noted that the insulating layer 22Z that covers all of them is further formed afterward and a through hole, the barrier layer 30B, and the upper contact layer 25B are sequentially formed. The through hole penetrates the insulating layer 22Z and reaches the upper electrode TE.

### [Workings and Effects of Imaging Device 1]

As described above, the imaging device 1 according to the present embodiment is provided with the hydrogen block layer 29 around the storage element 24. This makes it possible to prevent a degradation causing substance such as a hydrogen gas from reaching the storage element 24. The degradation causing substance such as a hydrogen gas is generated, for example, in a process of manufacturing the imaging device 1. This allows the imaging device 1 to effectively suppress the performance degradation of the storage element 24 and obtain excellent operational reliability. Further, if the imaging device 1 includes titanium in the lower electrode BE and the upper electrode TE provided to sandwich the storage element 24 in the Z axis direction, it is more effectively prevent the above-described degradation causing substance from reaching the storage element 24. Especially in a case where the upper electrode TE has the thickness ZTE greater than the thickness ZBE of the lower electrode BE, it is still more effectively prevent the degradation causing substance from entering the storage element 24. In addition, the thickness ZTE of the upper electrode TE greater than the thickness ZBE of the lower electrode BE allows the storage element 24 to be less damaged in another step after the storage element 24 is formed, for example, a hole-making step or the like of forming an opening on the side wall section SW for coupling the upper contact layer 25B to the upper electrode TE.

In addition, forming the lower contact layer 25A of the imaging device 1, for example, in a CVD method by using W (tungsten) makes it possible to achieve the lower contact layer 25A shaped to be long and narrow in the Z axis direction. The same applies to the upper contact layer 25B. This also supports a case where a large number of storage elements 24 are arranged in a narrow region, contributing to higher integration. Here, W (tungsten) tends to have less adhesion to a material included in an insulating layer 20Z, for example, SiO₂. Accordingly, the barrier layer 30A interposed between the lower contact layer 25A and the insulating layer 20Z makes it possible to increase the adhesion between the lower contact layer 25A and the insulating layer 20Z. The barrier layer 30A may be a stacked film of a TiN film covering the lower contact layer 25A and a Ti film covering the TiN film. In that case, the TiN film is excellent especially in adhesion to W (tungsten). The Ti film is excellent especially in adhesion to SiO₂. This makes it possible to still further increase the adhesion between the lower contact layer 25A and the insulating layer 20Z. In addition, in a case where the barrier layer 30A includes Ti (titanium), it is possible to occlude a degradation causing substance such as a hydrogen radical. This makes it possible to still further reduce the possibility of the storage element 24 to have performance degradation.

It is to be noted that a barrier layer including Ti (titanium) may be further formed in the imaging device 1 according to the present embodiment to cover each of the wiring lines 26 and each of the vias 27. This is because it is possible to more effectively prevent a degradation causing substance such as a hydrogen radical from reaching the storage element 24.

In addition, the imaging device 1 according to the present embodiment has a two-layer structure in which the surface 10S of the sensor board 10 and the surface 20S of the circuit board 20 are bonded together. The sensor board 10 includes the wiring layer 11 and the semiconductor layer 12. The wiring layer 11 and the semiconductor layer 12 are stacked in order from a position closer to the circuit board 20. The circuit board 20 includes the wiring layer 21, the storage element layer 22, and the semiconductor layer 23. The wiring layer 21, the storage element layer 22, and the semiconductor layer 23 are stacked in order from a position closer to the sensor board 10. This brings the wiring layer 11 of the sensor board 10 and the storage element 24 of the circuit board 20 closer to each other. This makes it possible to decrease the wiring line 26 and the via 27 in length. The wiring line 26 and the via 27 connect the electrode 13 of the wiring layer 11 of the sensor board 10 and the storage element 24 of the circuit board 20. This makes it possible to reduce the electric resistance of the wiring line 26 and the like. Moreover, it is possible to simplify the manufacturing process. Additionally, this makes it possible to suppress the wiring line 26 and the via 27 extending in the XY in-plane direction and achieve space saving, contributing to a decrease in the dimensions of the entire imaging device 1. The imaging device 1 according to the present embodiment is thus suitable for higher integration.

### 1-2. First Modification Example

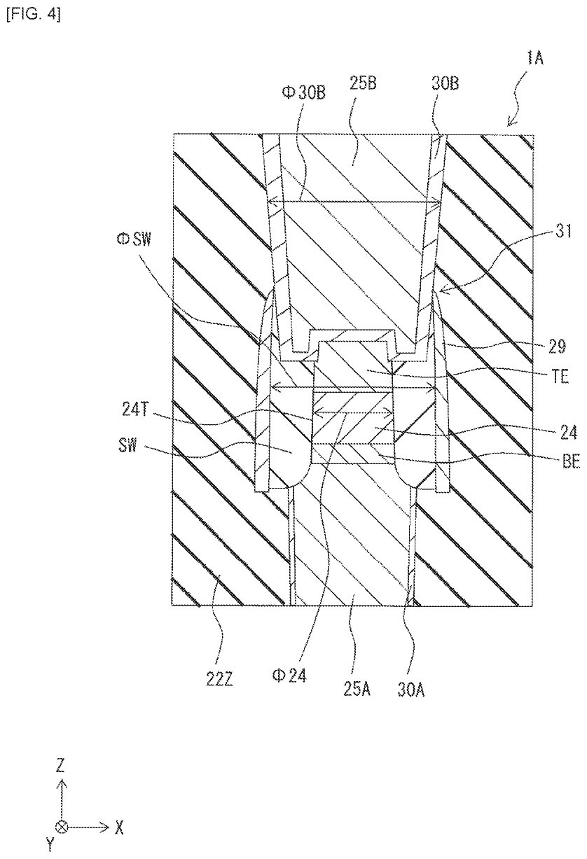

FIG. 4 is a detailed enlarged cross-sectional view of components near the storage element 24 in an imaging device 1A serving as a first modification example of the present disclosure. As illustrated in FIG. 4, the barrier layer 30B of the imaging device 1A that covers the upper contact layer 25B includes a portion having an outer diameter Φ30B greater than an outer diameter Φ24 of the storage element 24 in the XY in-plane direction. In addition, the barrier layer 30B includes a portion having the outer diameter Φ30B greater than an outer diameter ΦSW of the side wall section SW in the XY in-plane direction. This links the barrier layer 30B and the hydrogen block layer 29 together at a boundary position 31 with no gap. This makes it possible to prevent a degradation causing substance from entering the storage element 24 from a gap between the barrier layer 30B and the hydrogen block layer 29 via the side wall section SW. This allows the imaging device 1A to effectively suppress the performance degradation of the storage element 24 and obtain excellent operational reliability. It is to be noted that the barrier layer 30A covering the lower contact layer 25A and the hydrogen block layer 29 are electrically separated by the side wall section SW. This prevents the lower contact layer 25A and the upper contact layer 25B from being short-circuited via the hydrogen block layer 29.

### 1-3. Second Modification Example

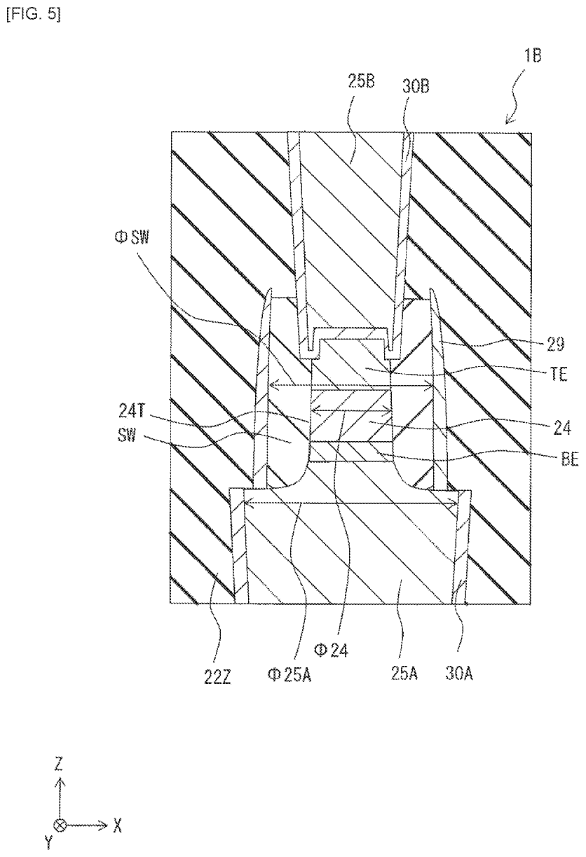

FIG. 5 is a detailed enlarged cross-sectional view of components near the storage element 24 in an imaging device 1B serving as a second modification example of the present disclosure. As illustrated in FIG. 5, the hydrogen block layer 29 and the lower contact layer 25A are coupled in the imaging device 1B. The lower portion of the side wall section SW is continuously covered with the hydrogen block layer 29 and the lower contact layer 25A. In the imaging device 1B, the dimensions or an outer diameter Φ25A of the outer edge of the upper end portion of the lower contact layer 25A, that is, the portion of the lower contact layer 25A opposed to the lower electrode BE and the side wall section SW is further greater than the dimensions or the outer diameter ΦSW of the outer edge of the side wall section SW.

In this way, the imaging device 1B serving as the second modification example has the larger outer diameter Φ25A of the lower contact layer 25A and has the lower portion of the side wall section SW continuously covered with the hydrogen block layer 29 and the lower contact layer 25A. This makes it possible to decrease the area of contact between the insulating layer 22Z and the side wall section SW in the imaging device 1B as compared with the imaging device 1. It is thus possible to further reduce degradation causing substances that enter the storage element 24 via the insulating layer 22Z and the side wall section SW. As a result, the imaging device 1B is able to more effectively suppress the performance degradation of the storage element 24 and obtain more excellent operational reliability.

### 1-4. Third Modification Example and Fourth Modification Example

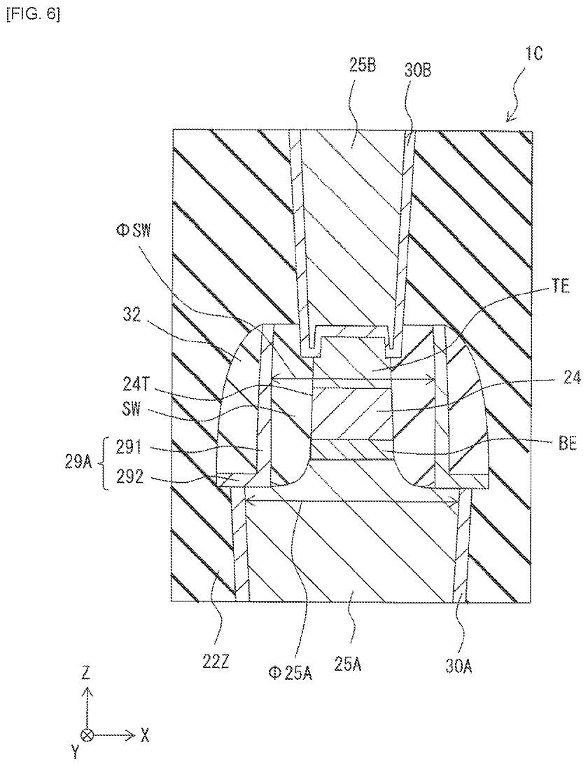

FIG. 6 is a detailed enlarged cross-sectional view of components near the storage element 24 in an imaging device 1C serving as a third modification example of the present disclosure. As illustrated in FIG. 6, the imaging device 1C includes a hydrogen block layer 29A in place of the hydrogen block layer 29. Except for this point, the imaging device 1C has substantially the same configuration as that of the imaging device 1 with respect to the other points. The hydrogen block layer 29A includes a first portion 291 and a second portion 292. The first portion 291 extends in the stacked direction (Z axis direction). The second portion 292 extends away from the storage element 24 in the XY plane orthogonal to the Z axis direction. The first portion 291 is a portion that covers the outer peripheral surface SWS of the side wall section SW. The second portion 292 is a portion that is coupled to the lower end of the first portion 291 and outwardly protrudes from the position coupled to the lower end of the first portion 291. In this way, the hydrogen block layer 29A of the imaging device 1C includes the second portion 292 in addition to the first portion 291. This makes it possible to increase the amount of hydrogen occluded near the storage element 24 as compared with the imaging device 1. This makes it possible to more effectively prevent a degradation causing substance from reaching the storage element 24.

Further, as with the imaging device 1B serving as the above-described second modification example of the present disclosure, the imaging device 1C illustrated in FIG. 6 has the larger outer diameter Φ25A of the lower contact layer 25A and has the lower portion of the side wall section SW continuously covered with the hydrogen block layer 29A and the lower contact layer 25A. That is, the second portion 292 is linked to both the first portion 291 and the lower contact layer 25A. It is thus possible to further reduce degradation causing substances that enter the storage element 24 via the insulating layer 22Z and the side wall section SW. As a result, the imaging device 1C is able to more effectively suppress the performance degradation of the storage element 24 and obtain more excellent operational reliability.

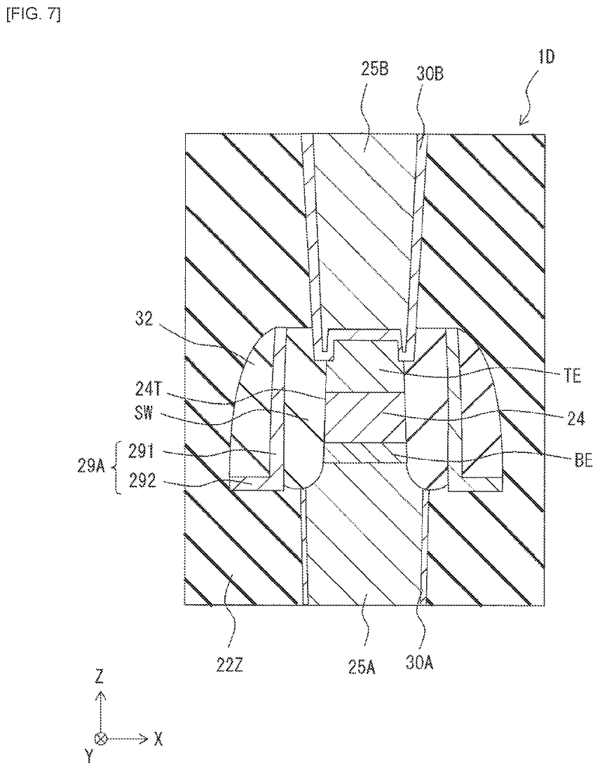

It is to be noted that the outer diameter Φ25A of the lower contact layer 25A may be as large as an outer diameter Φ25B of the upper contact layer 25B to space apart the hydrogen block layer 29A and the lower contact layer 25A as with an imaging device 1D serving as a fourth modification example of the present disclosure illustrated in FIG. 7.

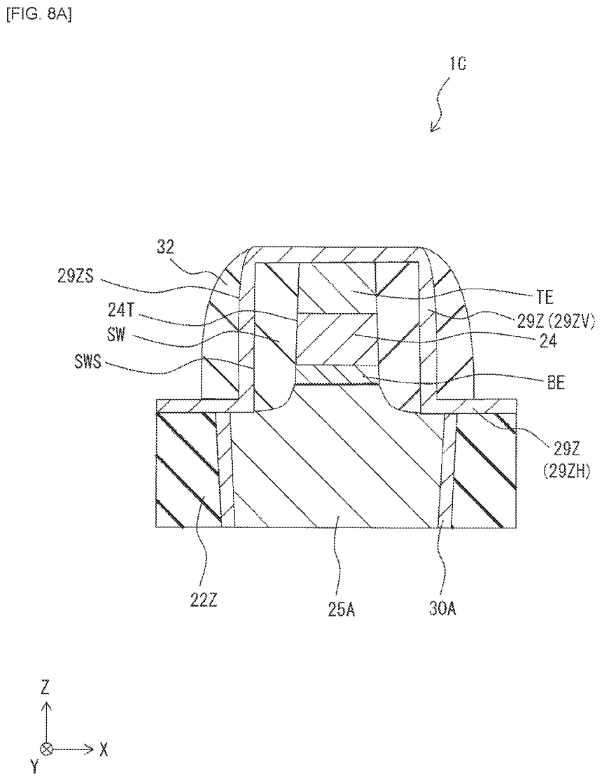

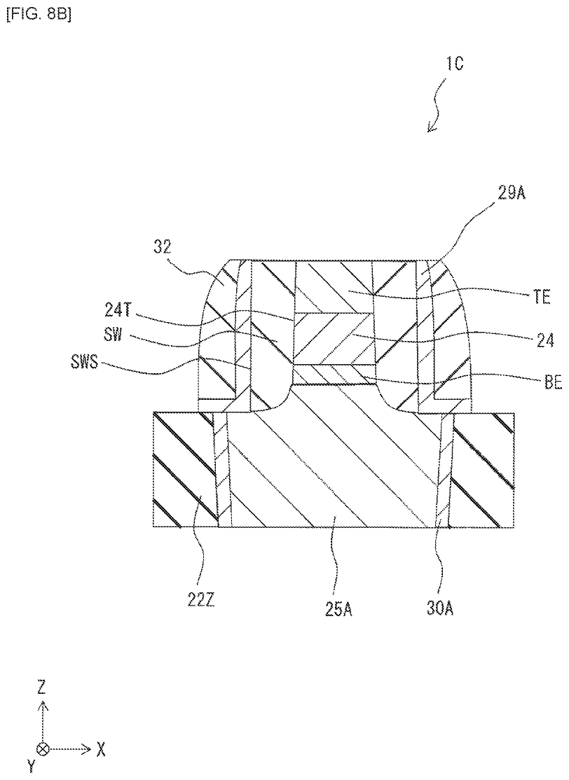

In addition, it is possible to form the hydrogen block layer 29A in the imaging device 1C illustrated in FIG. 6, for example, as follows. The following describes a method of forming the hydrogen block layer 29A with reference to FIGS. 8A and 8B. Each of FIGS. 8A and 8B is an enlarged cross-sectional view of a step of the method of forming the hydrogen block layer 29A provided near the storage element 24 illustrated in FIG. 6.

First, the metal layer 29Z is formed in the procedures illustrated in FIGS. 3A to 3D as with the imaging device 1 according to the above-described first embodiment. The metal layer 29Z covers the insulating layer 22Z, the side wall section SW, and a stack including the storage element 24.

Next, an insulating film including SiO2 or the like is formed to cover the entire metal layer 29Z and the insulating film is then selectively removed by etching back, thereby selectively leaving an insulating layer 32 unremoved as illustrated in FIG. 8A. The insulating layer 32 covers an outer surface 29ZS of the metal layer 29Z, that is, the surface opposite to each of the end surfaces 24T of the storage element 24 with the side wall section SW interposed therebetween. The insulating layer 32 covers both a vertical portion 29ZV and a portion of a horizontal portion 29ZH of the metal layer 29Z. The vertical portion 29ZV covers the outer peripheral surface SWS of the side wall section SW. The horizontal portion 29ZH extends in the XY plane to covers the insulating layer 22Z.

Next, as illustrated in FIG. 8B, a portion of the metal layer 29Z that is not covered with the insulating layer 32 is selectively removed to expose the upper end of the upper electrode TE and the upper end of the side wall section SW. As a result, the hydrogen block layer 29A is formed.

### 2. Second Embodiment

### 2-1. Basic Form

### [Configuration of Imaging Device 2]

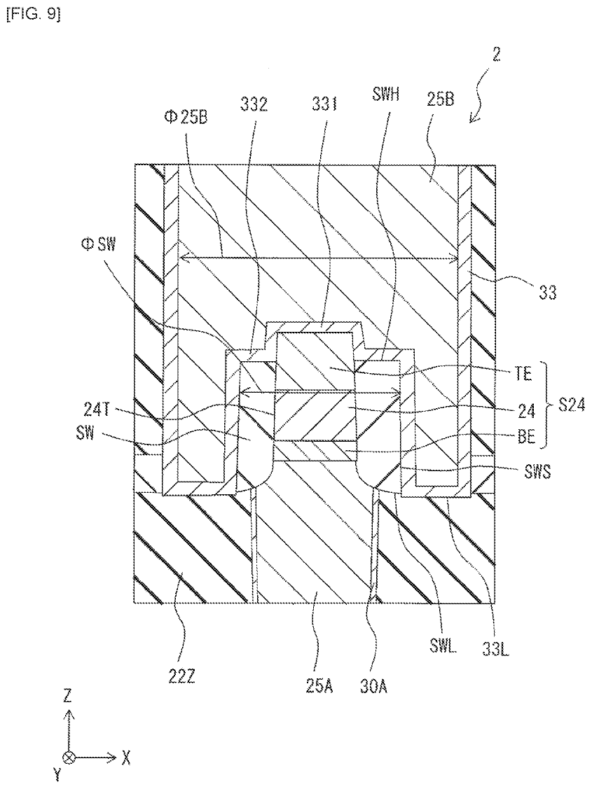

FIG. 9 illustrates a cross-sectional configuration example of a main portion of an imaging device 2 serving as a second embodiment of the present disclosure. In the above-described first embodiment, the hydrogen block layer 29 and the barrier layer 30B are provided as different entities. The hydrogen block layer 29 surrounds the end surfaces 24T of the storage element 24. The barrier layer 30B covers the upper contact layer 25B. In contrast, the imaging device 2 according to the second embodiment includes a hydrogen block layer 33 that is integrally formed to surround the end surfaces 24T of the storage element 24 and cover even the upper contact layer 25B as illustrated in FIG. 9. Except for this point, the imaging device 2 has substantially the same configuration as that of the imaging device 1 according to the above-described first embodiment.

As illustrated in FIG. 9, the dimensions or the outer diameter Φ25B of the outer edge of the upper contact layer 25B is greater than the dimensions or the outer diameter ΦSW of the outer edge of the side wall section SW in the XY plane. The hydrogen block layer 33 is provided to cover the upper contact layer 25B and cover the entire outer peripheral surface SWS from the lower edge SWL of the side wall section SW to an upper end portion SWH in the Z axis direction. Further, the hydrogen block layer 33 includes a first boundary portion 331 and a second boundary portion 332. The first boundary portion 331 separates the upper contact layer 25B and the stack S24 including the storage element 24. The second boundary portion 332 separates the upper contact layer 25B and the side wall section SW and is provided to be continuous to the first boundary portion 331. In addition, the hydrogen block layer 33 and the lower contact layer 25A are spaced apart and insulated from each other by the insulating layer 22Z.

### [Method of Forming Hydrogen Block Layer 33]

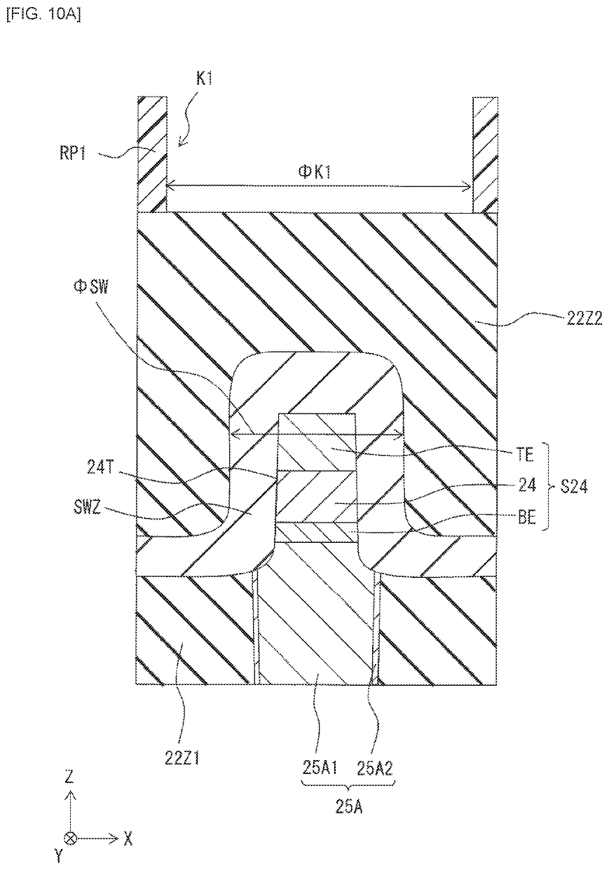

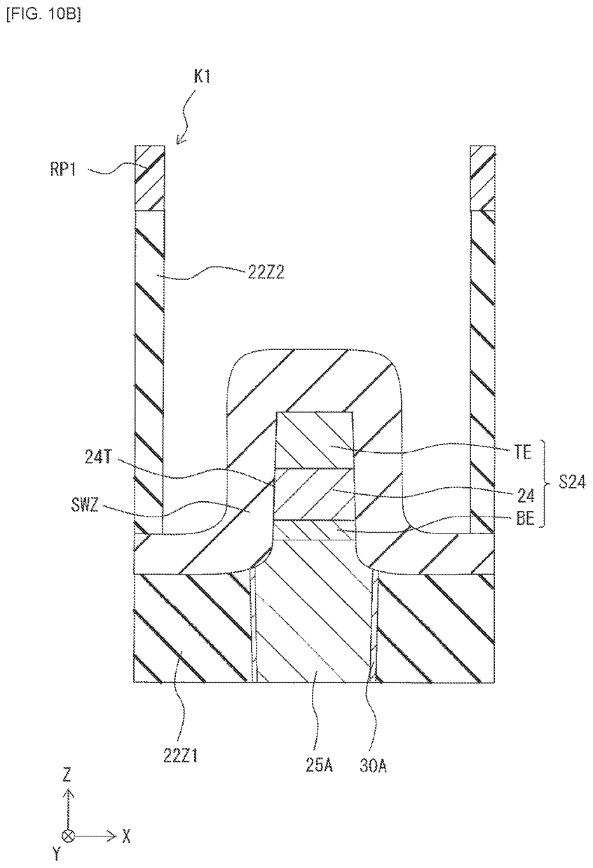

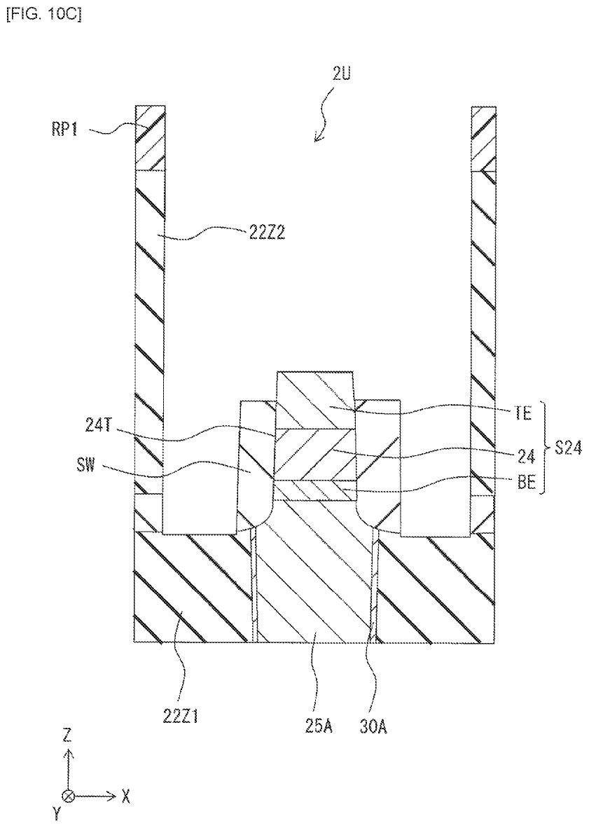

Next, with reference to FIGS. 10A to 10C in addition to FIG. 9, a method of forming the hydrogen block layer 33 of the imaging device 2 is described. Each of FIGS. 10A to 10C is an enlarged cross-sectional view of a step of the method of forming the hydrogen block layer 33 provided near the storage element 24 illustrated in FIG. 9.

First, the protective layer SWZ is formed by using SiN or the like in the procedures illustrated in FIGS. 3A and 3B to uniformly cover all the insulating layer 22Z, the lower contact layer 25A, and the stack S24 as with the imaging device 1 according to the above-described first embodiment.

Next, as illustrated in FIG. 10A, an insulating layer 22Z2 is formed to cover the entire the protective layer SWZ. It is to be noted that FIG. 10A and the subsequent figures describe the insulating layer 22Z in which the lower contact layer 25A is embedded as an insulating layer 22Z1 and describe the insulating layer 22Z covering the protective layer SWZ as the insulating layer 22Z2. Further, a resist pattern RP1 having an opening K1 is selectively formed on the upper surface of the insulating layer 22Z2, for example, in a photolithography method. In that case, the opening K1 has an inner diameter ΦK1 greater than the outer diameter ΦSW of a portion serving as the side wall section SW later in the XY in-plane direction.

Next, an exposed portion of the insulating layer 22Z2 that is not covered with the resist pattern RP1 is selectively removed by dry etching. This causes the protective layer SWZ to appear again as illustrated in FIG. 10B. Afterward, a portion of the protective layer SWZ that covers the upper portion of the stack S24 and a portion of the protective layer SWZ that covers the insulating layer 22Z1 are selectively removed by dry etching. As a result, as illustrated in FIG. 10C, a recessed section 2U is formed. The side wall section SW covering the end surfaces 24T of the storage element 24 is left unremoved. Afterward, the hydrogen block layer 33 including Ti (titanium) is formed, for example, in a sputtering method to cover the inner surface of the recessed section 2U. Further, the upper contact layer 25B including W (tungsten) is formed, for example, in a CVD method to fill the recessed section 2U.

### [Workings and Effects of Imaging Device 2]

As described above, the imaging device 2 according to the present embodiment includes the hydrogen block layer 33 that surrounds the side wall section SW in the XY plane and covers even the upper contact layer 25B. This makes it possible to effectively prevent a degradation causing substance from entering the storage element 24. This allows the imaging device 2 to effectively suppress the performance degradation of the storage element 24 and obtain excellent operational reliability.

Especially in the imaging device 2, the upper contact layer 25B has the outer diameter Φ25B greater than the outer diameter ΦSW of the side wall section SW in the XY plane. This allows the hydrogen block layer 33 to have larger surface area, for example, than the surface area of the hydrogen block layer 29 according to the first embodiment. This makes it possible to increase the amount of hydrogen occluded in the hydrogen block layer 33 and more effectively prevent a degradation causing substance from entering the storage element 24.

Further, it is possible to simplify the manufacturing process of the imaging device 2 as compared with that of the imaging device 1 provided with the hydrogen block layer 29 surrounding the side wall section SW and the barrier layer 30B covering the upper contact layer 25B as different entities. This is because it is necessary in the imaging device 1 to individually form the hydrogen block layer 29 and the barrier layer 30B in individual steps, but it is possible in the imaging device 2 to collectively form the hydrogen block layer 33 to surround the side wall section SW and cover the upper contact layer 25B.

### 2-2. Fifth Modification Example

### [Configuration of Imaging Device 2A]

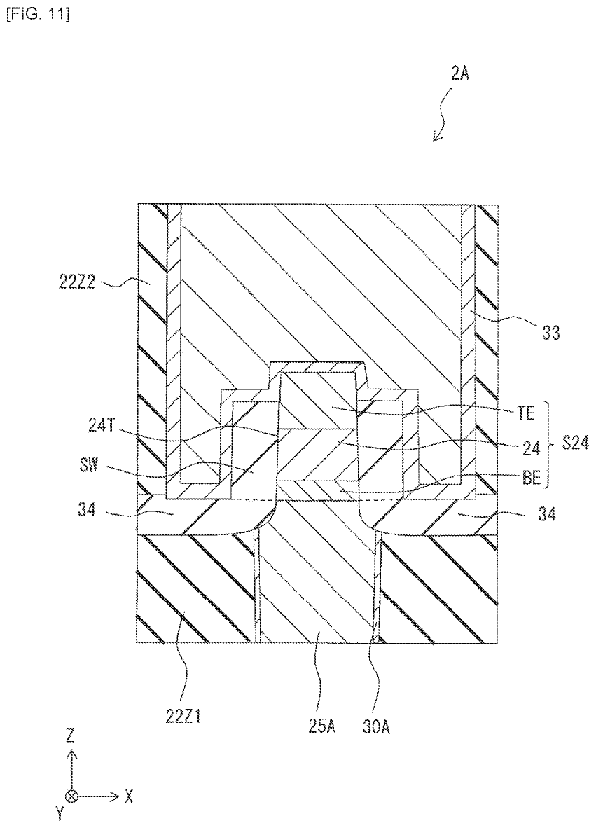

FIG. 11 is a detailed enlarged cross-sectional view of components near the storage element 24 in an imaging device 2A serving as a fifth modification example of the present disclosure. As illustrated in FIG. 11, the imaging device 2A further includes an insulating layer 34 that is linked to the lower end portion of the side wall section SW and extends away from the storage element 24 in the XY in-plane direction. The side wall section SW covers the end surfaces 24T of the storage element 24. In the imaging device 2A, the side wall section SW is a specific example corresponding to a “first protective portion” of a “protective film” of the present disclosure. The insulating layer 34 is a specific example corresponding to a “second protective portion” of the “protective film” of the present disclosure. That is, in the imaging device 2A, the hydrogen block layer 33 is separated from the lower contact layer 25A by the insulating layer 34. Except for this point, the imaging device 2A has substantially the same configuration as that of the imaging device 2A with respect to the other points.

### [Method of Forming Hydrogen Block Layer 33]

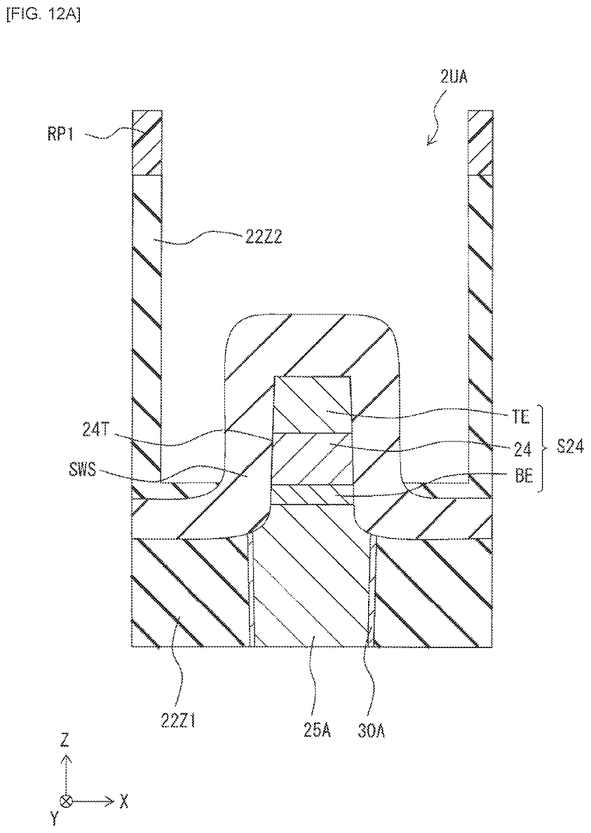

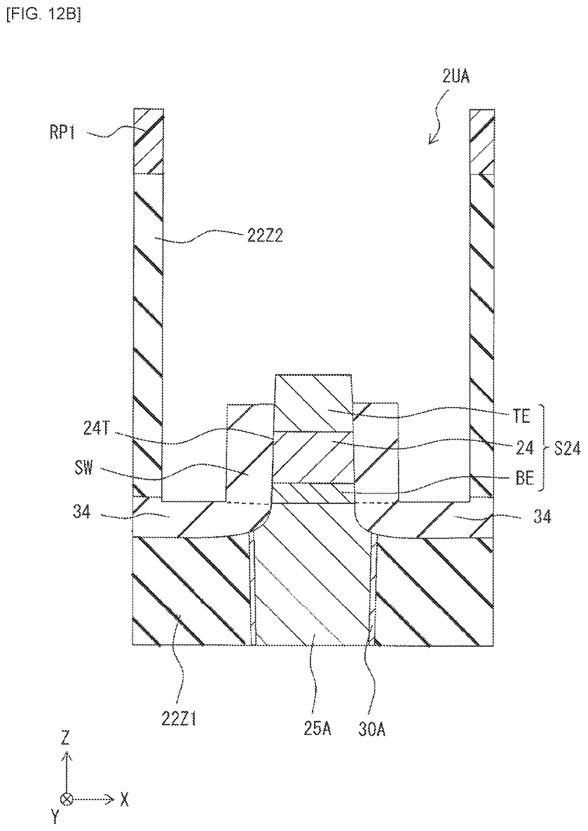

Next, with reference to FIGS. 12A and 12B in addition to FIG. 11, a method of forming the hydrogen block layer 33 of the imaging device 2A is described. Each of FIGS. 12A and 12B is an enlarged cross-sectional view of a step of the method of forming the hydrogen block layer 33 provided near the storage element 24 illustrated in FIG. 11.

First, the protective layer SWZ is formed by using SiN or the like to uniformly cover all the insulating layer 22Z, the lower contact layer 25A, and the stack S24 as with the imaging device 2 according to the above-described second embodiment. Afterward, the insulating layer 22Z2 is formed. Further, a resist pattern RP1 having an opening K1 is selectively formed on the upper surface of the insulating layer 22Z2, for example, in a photolithography method. In that case, the opening K1 has an inner diameter ΦK1 greater than the outer diameter ΦSW of a portion serving as the side wall section SW later in the XY in-plane direction (see FIG. 10A).

Next, an exposed portion of the insulating layer 22Z2 that is not covered with the resist pattern RP1 is selectively removed by dry etching. This causes the protective layer SWZ to appear again as illustrated in FIG. 12A. In that case, as illustrated in FIG. 12A, the insulating layer 22Z2 may be slightly left unremoved not to expose a portion of the protective layer SWZ that covers the insulating layer 22Z1.

Next, a portion of the protective layer SWZ that covers the upper portion of the stack S24 is selectively removed by dry etching. As a result, as illustrated in FIG. 12B, a recessed section 2UA is formed. The side wall section SW covering the end surfaces 24T of the storage element 24 and the insulating layer 34 covering the insulating layer 22Z1 are left unremoved.

Finally, the hydrogen block layer 33 including Ti (titanium) is formed, for example, in a sputtering method to cover the inner surface of the recessed section 2UA. Afterward, the upper contact layer 25B including W (tungsten) is formed, for example, in a CVD method to fill the recessed section 2UA.

### [Workings and Effects of Imaging Device 2A]

In this way, the imaging device 2A serving as the fifth modification example is provided with the insulating layer 34 between the hydrogen block layer 33 and the lower contact layer 25A. This makes it possible to increase the closest distance between the hydrogen block layer 33 and the lower contact layer 25A, for example, as compared with the imaging device 2 in FIG. 9. This facilitates the imaging device 2A to avoid a short circuit between the hydrogen block layer 33 and the lower contact layer 25A even in a case where the position of the recessed section 2UA in the XY plane and the position of the lower contact layer 25A in the XY plane do not match each other when the hydrogen block layer 33 is formed. The imaging device 2A is thus superior to the imaging device 2 in manufacturability.

### 2-3. Sixth Modification Example

### [Configuration of Imaging Device 2B]

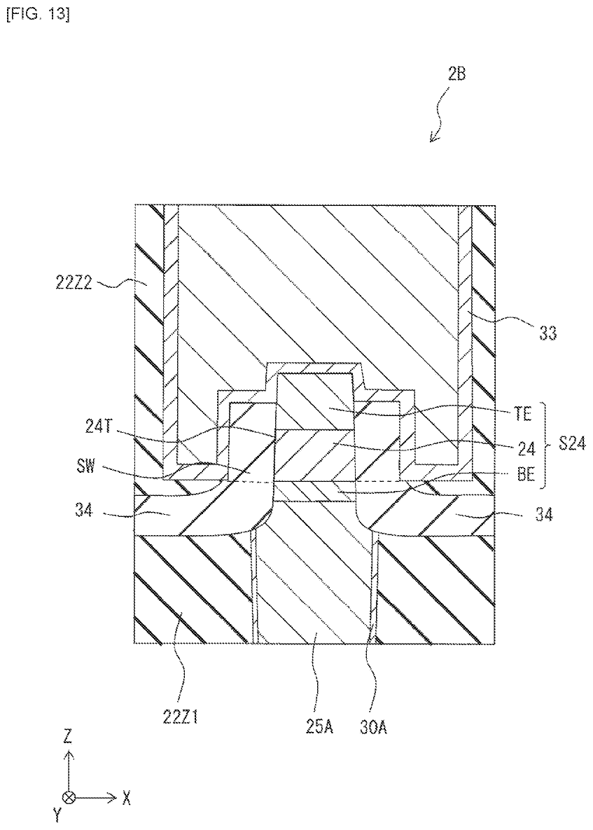

FIG. 13 is a detailed enlarged cross-sectional view of components near the storage element 24 in an imaging device 2B serving as a sixth modification example of the present disclosure. In the above-described imaging device 2A, the insulating layer 22Z2 is removed to the depth position corresponding to the lower electrode BE to form the hydrogen block layer 33. In contrast, in the imaging device 2B serving as the sixth modification example of the present disclosure, the insulating layer 22Z2 is removed to the depth position corresponding to the storage element 24 to form the hydrogen block layer 33.

### 2-4. Seventh Modification Example

### [Configuration of Imaging Device 2C]

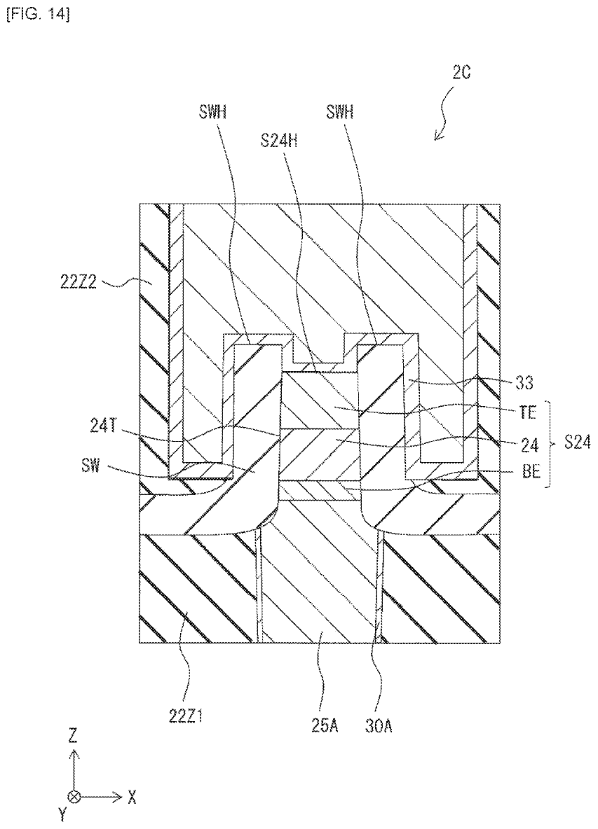

FIG. 14 is a detailed enlarged cross-sectional view of components near the storage element 24 in an imaging device 2C serving as a seventh modification example of the present disclosure. In the imaging device 2C, the upper end portion SWH of the side wall section SW opposite to the lower contact layer 25A protrudes in the Z axis direction more than an upper end portion S24H of the stack S24 opposite to the lower contact layer 25A. The stack S24 includes the storage element 24.

### [Method of Forming Hydrogen Block Layer 33]

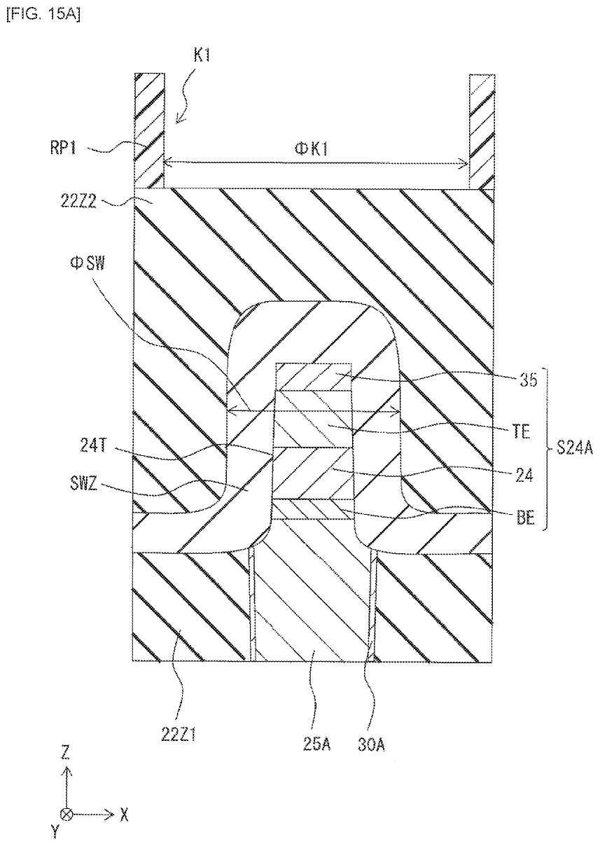

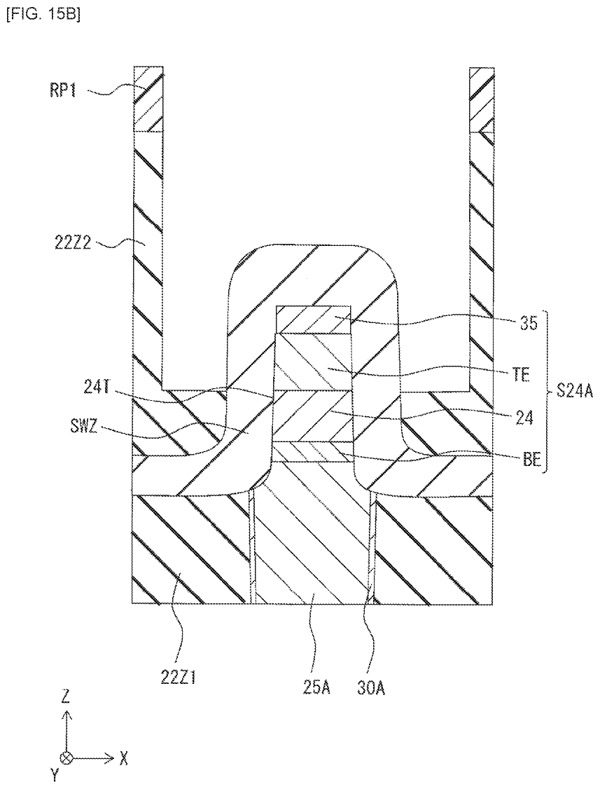

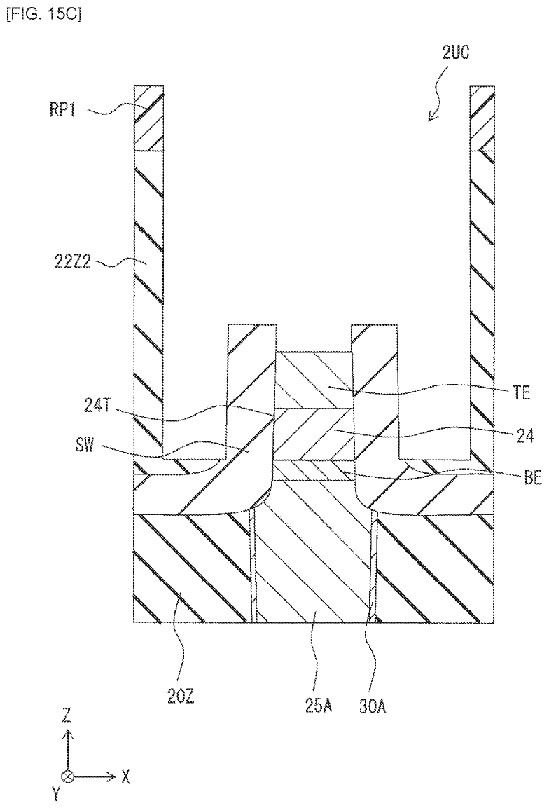

Next, with reference to FIGS. 15A to 15C in addition to FIG. 14, a method of forming the hydrogen block layer 33 of the imaging device 2C is described. Each of FIGS. 15A to 15C is an enlarged cross-sectional view of a step of the method of forming the hydrogen block layer 33 provided near the storage element 24 illustrated in FIG. 14.

First, the protective layer SWZ is formed by using SiN or the like in the procedures illustrated in FIGS. 3A and 3B to uniformly cover all the insulating layer 22Z, the lower contact layer 25A, and a stack S24A as with the imaging device 1 according to the above-described first embodiment. The stack S24A is, however, obtained by stacking the lower electrode BE, the storage element 24, and the upper electrode TE and then further forming an insulating layer 35 including SiO₂ or the like (see FIG. 15A).

Next, as illustrated in FIG. 15A, an insulating layer 22Z2 is formed to cover the entire the protective layer SWZ. Further, a resist pattern RP1 having an opening K1 is selectively formed on the upper surface of the insulating layer 22Z2, for example, in a photolithography method. In that case, the opening K1 has an inner diameter ΦK1 greater than the outer diameter ΦSW of a portion serving as the side wall section SW later in the XY in-plane direction.

Next, an exposed portion of the insulating layer 22Z2 that is not covered with the resist pattern RP1 is selectively removed by dry etching. In that case, as illustrated in FIG. 15B, the insulating layer 22Z2 is left unremoved not to expose a portion of the protective layer SWZ that covers the insulating layer 22Z1. This causes the portion of the protective layer SWZ to appear again as illustrated in FIG. 15B.

Afterward, a portion of the protective layer SWZ that covers the upper portion of the stack S24 and the insulating layer 35 are selectively removed by dry etching. As a result, as illustrated in FIG. 15C, a recessed section 2UC is formed and the side wall section SW including the upper end portion SWH is left unremoved. The upper end portion SWH protrudes more than the upper end portion S24H of the stack S24. Afterward, the hydrogen block layer 33 including Ti (titanium) is formed, for example, in a sputtering method to cover the inner surface of the recessed section 2UC. Further, the upper contact layer 25B including W (tungsten) is formed, for example, in a CVD method to fill the recessed section 2UC.

### [Workings and Effects of Imaging Device 2C]

In this way, the side wall section SW of the imaging device 2C includes the upper end portion SWH that protrudes more than the upper end portion S24H of the stack S24. This allows the hydrogen block layer 33 covering them to have larger surface area than the surface area of the hydrogen block layer 33, for example, in the imaging device 2. This makes it possible to increase the amount of hydrogen occluded in the hydrogen block layer 33 and more effectively prevent a degradation causing substance from entering the storage element 24.

### 3. Third Embodiment: Example of Application to Electronic Apparatus

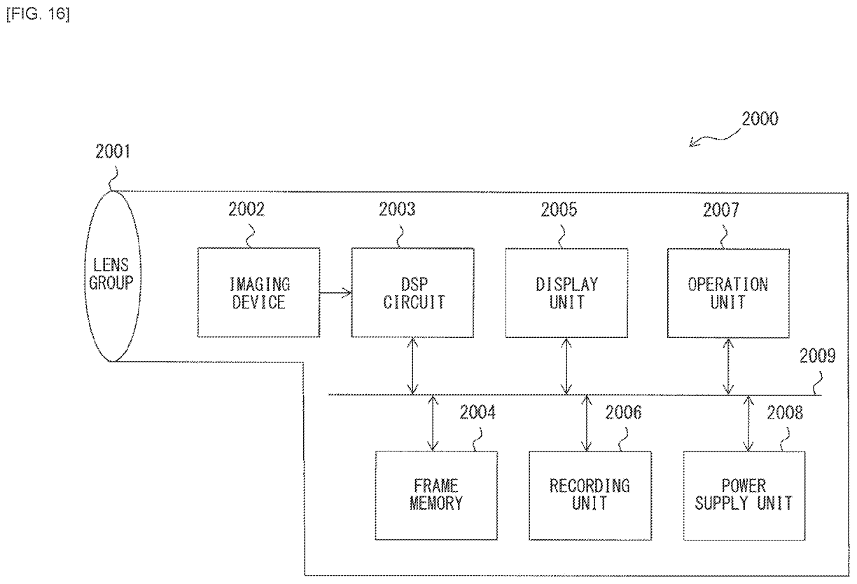

FIG. 16 is a block diagram illustrating a configuration example of a camera 2000 serving an electronic apparatus to which the present technology is applied.

The camera 2000 includes an optical unit 2001 including a lens group and the like, an imaging device (imaging device) 2002 to which the above-described imaging device 1, 1A to 1D, 2, 2A to 2D, or the like (referred to as imaging device 1 or the like) is applied, and a DSP (Digital Signal Processor) circuit 2003 that is a camera signal processing circuit. In addition, the camera 2000 also includes a frame memory 2004, a display unit 2005, a recording unit 2006, an operation unit 2007, and a power supply unit 2008. The DSP circuit 2003, the frame memory 2004, the display unit 2005, the recording unit 2006, the operation unit 2007, and the power supply unit 2008 are coupled to each other via a bus line 2009.

The optical unit 2001 takes in incident light (image light) from a subject to form an image on an imaging surface of the imaging device 2002. The imaging device 2002 converts the amount of incident light formed, as an image, on the imaging surface by the optical unit 2001 into an electric signal on a pixel unit basis and outputs the converted electric signal as a pixel signal.

The display unit 2005 includes, for example, a panel-type display device such as a liquid crystal panel or an organic EL panel and displays a moving image or a still image captured by the imaging device 2002. The recording unit 2006 records the moving image or the still image captured by the imaging device 2002 in a recording medium such as a hard disk or a semiconductor memory.

The operation unit 2007 issues an operation instruction about various functions of the camera 2000 under an operation of a user. The power supply unit 2008 appropriately supplies the DSP circuit 2003, the frame memory 2004, the display unit 2005, the recording unit 2006, and the operation unit 2007 with various types of power for operations of the supply targets.

As described above, the use of the above-described imaging device 1 or the like as the imaging device 2002 makes it possible to expect a favorable image to be acquired.

### 4. Example of Practical Application to Mobile Body

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an airplane, a drone, a vessel, or a robot.

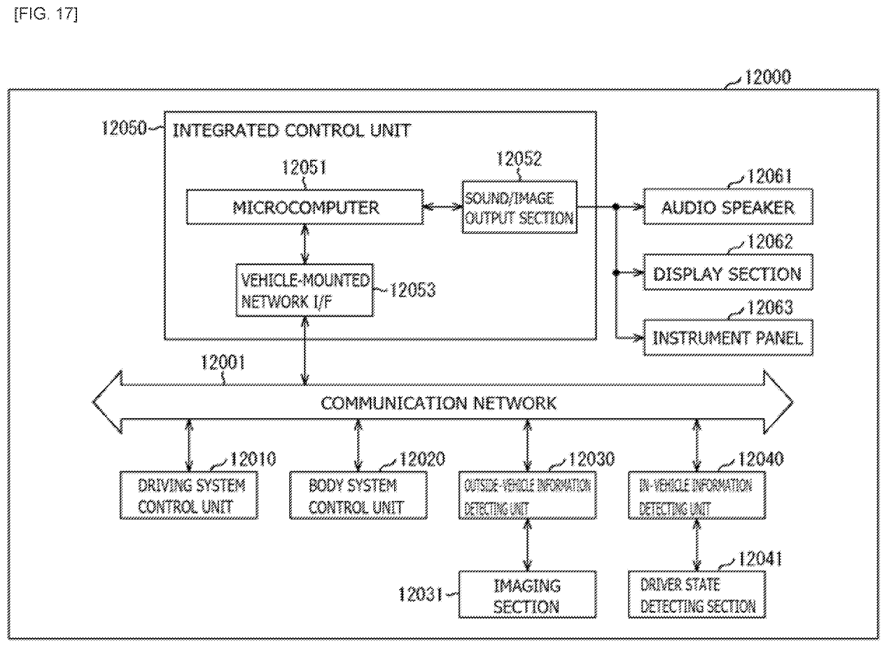

FIG. 17 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 17, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 17, an audio speaker 12061, a display section 12062, and an instrument panel 12063 are illustrated as the output device. The display section 12062 may, for example, include at least one of an on-board display and a head-up display.

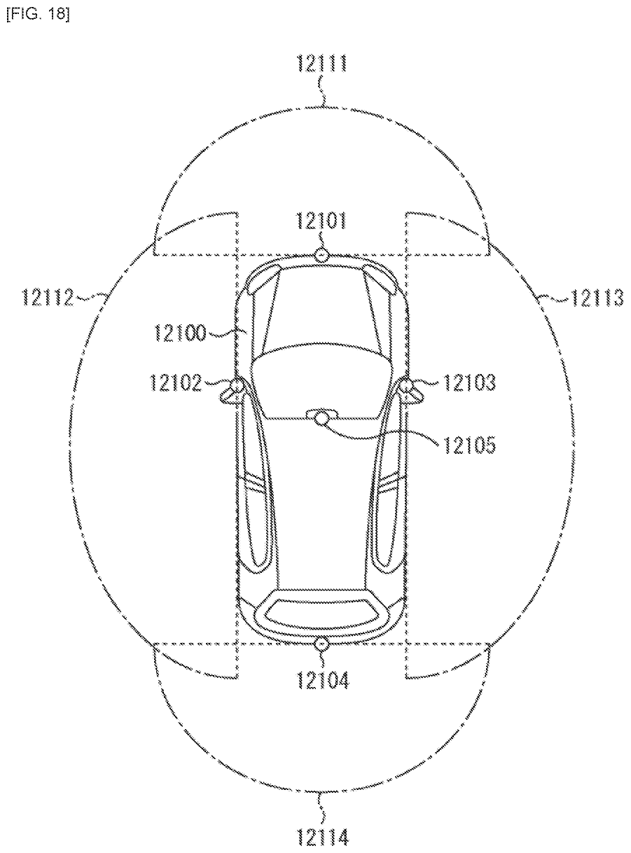

FIG. 18 is a diagram depicting an example of the installation position of the imaging section 12031.

In FIG. 18, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 18 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The above has described the example of the vehicle control system to which the technology according to the present disclosure may be applied. The technology according to the present disclosure may be applied to the imaging section 12031 among the above-described components. Specifically, the imaging device 1 or the like illustrated in FIG. 1 or the like is applicable to the imaging section 12031. It is possible to expect an excellent operation of the vehicle control system by applying the technology according to the present disclosure to the imaging section 12031.

### 5. Example of Practical Application to Endoscopic Surgery System

The technology (the present technology) according to the present disclosure is applicable to a variety of products. For example, the technology according to the present disclosure may be applied to an endoscopic surgery system.

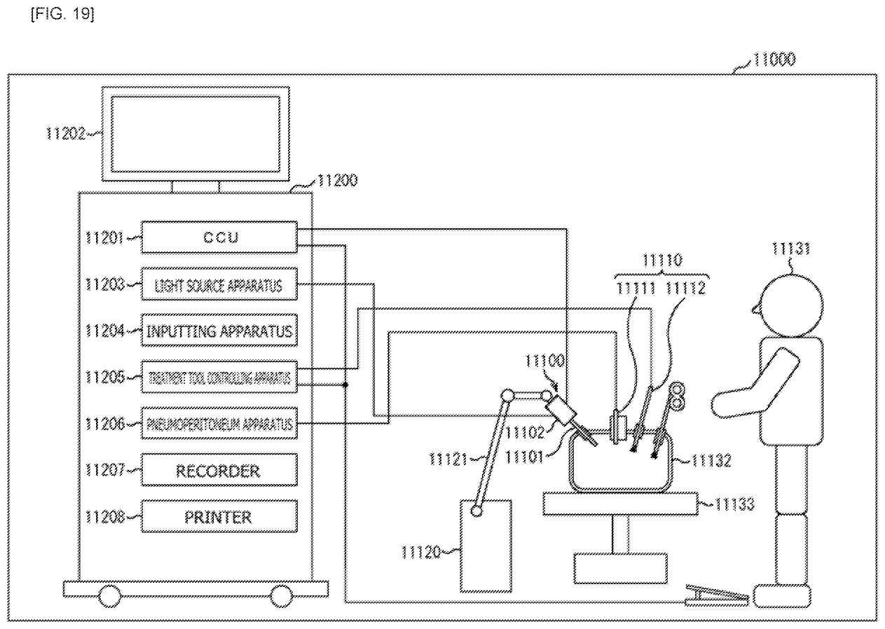

FIG. 19 is a view depicting an example of a schematic configuration of an endoscopic surgery system to which the technology according to an embodiment of the present disclosure (present technology) can be applied.

In FIG. 19, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

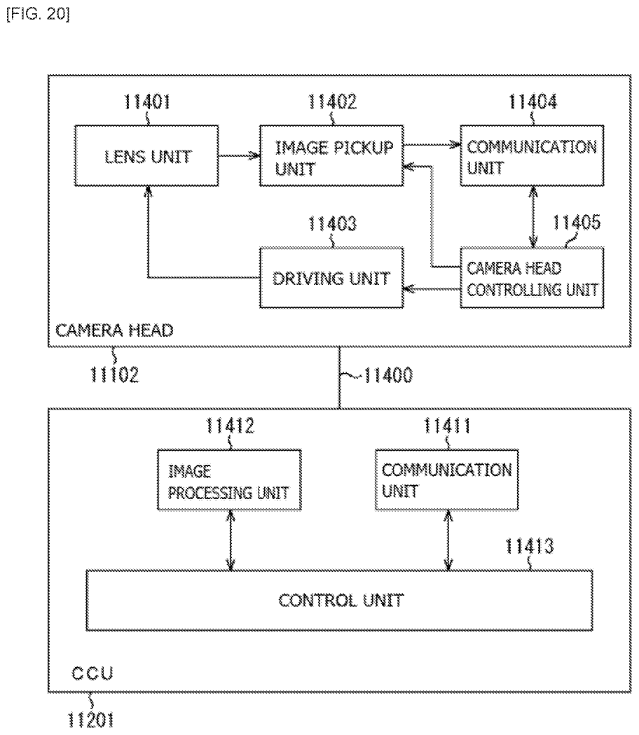

FIG. 20 is a block diagram depicting an example of a functional configuration of the camera head 11102 and the CCU 11201 depicted in FIG. 19.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The above has described the example of the endoscopic surgery system to which the technology according to the present disclosure may be applied. The technology according to the present disclosure may be applied to, for example, the image pickup unit 11402 of the camera head 11102 among the above-described components. Specifically, it is possible to apply the imaging device 1 or the like illustrated in FIG. 1 to the image pickup unit 11402. The application of the technology according to the present disclosure to the image pickup unit 11402 allows excellent operational reliability to be obtained.

It is to be noted that the endoscopic surgery system has been described here as an example, but the technology according to the present disclosure may be additionally applied, for example, to a microscopic surgery system or the like.

### 6. Other Modification Examples

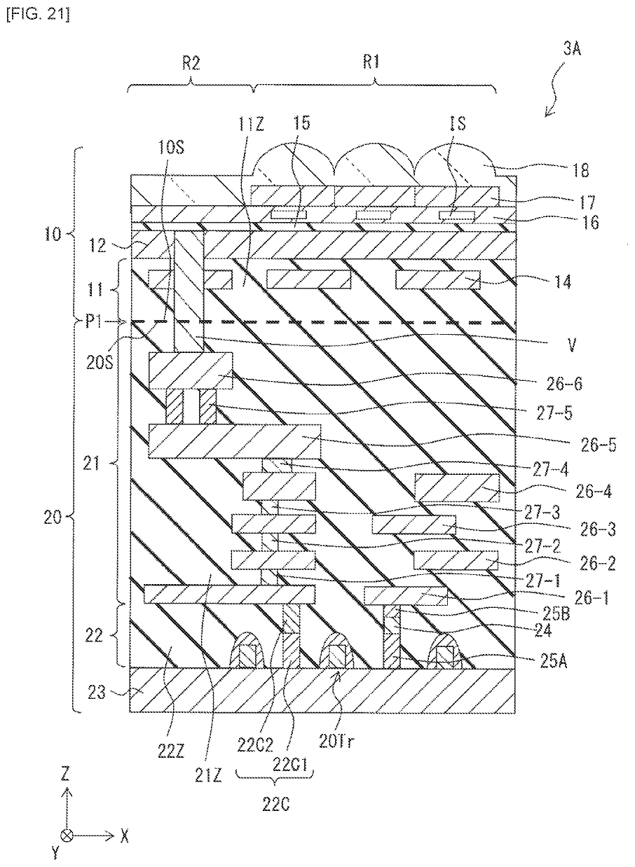

Although the present disclosure has been described above with reference to several embodiments and modification examples, the present disclosure is not limited to the above-described embodiments and the like. Various modifications may be made. For example, the imaging device 1 according to the above-described first embodiment has the electrode 13 exposed from the surface 10S and the electrode 28 exposed from the surface 20S have Cu—Cu junction, but the present disclosure is not limited thereto. The present disclosure is a concept including even an imaging device 3A serving as an eighth modification example of the present disclosure illustrated in FIG. 21. In the imaging device 3A, a via V that penetrates the surface 10S and the surface 20S couples the wiring line 14 of the sensor board 10 and the wiring line 26-6 of the circuit board 20. In addition, the imaging device 3A does not include the electrode 13 exposed from the surface 10S or the electrode 28 exposed from the surface 20S. Except for these points, the imaging device 3A has substantially the same configuration as that of the imaging device 1 according to the above-described first embodiment with respect to the other points.

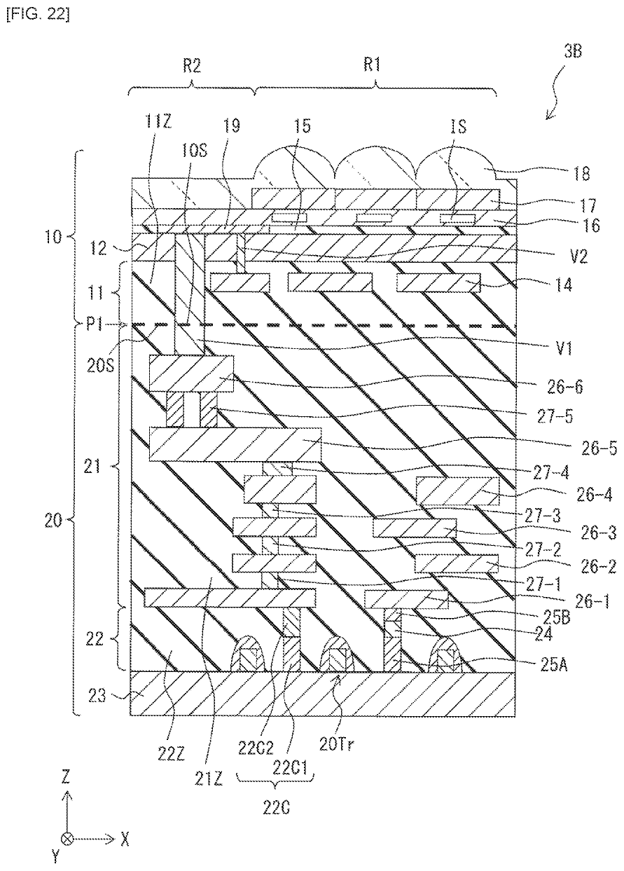

In addition, the present disclosure is a concept including even an imaging device 3B serving as a ninth modification example of the present disclosure illustrated in FIG. 22. The imaging device 3B is provided with a via V1, a wiring line 19, and a via V2. The via V1 is reaches the semiconductor layer 16 from the wiring line 26-6 through the surface 20S, the surface 10S, the wiring layer 11, and the semiconductor layer 12. The wiring line 19 is provided to the insulating layer 15 and coupled to the via V1. The via V2 reaches the wiring line 14 from the wiring line 19 through the semiconductor layer 12. In addition, as with the imaging device 1A, the imaging device 1B does not include the electrode 13 exposed from the surface 10S or the electrode 28 exposed from the surface 20S. Except for these points, the imaging device 3B has substantially the same configuration as that of the imaging device 1 according to the above-described first embodiment with respect to the other points.

In addition, imaging devices have been exemplified in the above-described embodiments and the like, but the semiconductor device according to the present disclosure is not limited thereto.

The semiconductor device according to the embodiment of the present disclosure prevents hydrogen from entering the storage element and is thus excellent in operational reliability. It is to be noted that the effects of the present disclosure are not limited thereto, but may be any of the effects described herein.

The effects described herein are merely examples, but not limited thereto. Other effects may be included. In addition, the present technology may have the following configurations.

(1)

A semiconductor device including:

a storage element;

a first contact that is electrically coupled to the storage element;

a second contact that is positioned on an opposite side to the first contact in a first direction, the second contact being electrically coupled to the storage element;

a protective film that surrounds the storage element in a first plane orthogonal to the first direction; and

a first hydrogen block layer that surrounds the protective film in the first plane.

(2)

The semiconductor device according to (1), in which the protective film is provided between a position of a first edge of the first hydrogen block layer and a position of a second edge of the first hydrogen block layer in the first direction.

(3)

The semiconductor device according to (1) and (2), further including a second hydrogen block layer that covers the first contact, in which the first hydrogen block layer and the second hydrogen block layer are linked.

(4)

The semiconductor device according to (3), in which the first contact includes a portion having an outer diameter greater than an outer diameter of the protective film in the first plane.

(5)

The semiconductor device according to any one of (1) to (4), in which the first hydrogen block layer and the second contact are coupled, and the protective film is continuously covered with the first hydrogen block layer and the second contact.

(6)

The semiconductor device according to (5), in which a dimension of an outer edge of a portion of the second contact opposed to the protective film and the storage element is greater than a dimension of an outer edge of the protective film in the first plane.

(7)

The semiconductor device according to any one of (1) to (6), in which the first hydrogen block layer includes

a first portion that extends in the first direction to cover an outer peripheral surface of the protective film, and

a second portion that is linked to both the first portion and the second contact, the second portion extending away from the storage element in a direction orthogonal to the first direction.

(8)

A semiconductor device including:

a storage element;

a first contact that is electrically coupled to the storage element;

a second contact that is positioned on an opposite side to the first contact in a first direction, the second contact being electrically coupled to the storage element;

a protective film that surrounds the storage element in a first plane orthogonal to the first direction; and

a hydrogen block layer that surrounds at least a portion of the protective film and covers the first contact in the first plane, the hydrogen block layer being insulated from the second contact.

(9)

The semiconductor device according to (8), in which a dimension of an outer edge of the first contact is greater than a dimension of an outer edge of the protective film in the first plane.

(10)

The semiconductor device according to (8) and (9), in which the hydrogen block layer includes a first boundary portion and a second boundary portion, the first boundary portion separating the first contact and the storage element, the second boundary portion separating the first contact and the protective film and being provided to be continuous to the first boundary portion.

(11)

The semiconductor device according to any one of (8) to (10), in which the protective film includes

a first protective portion that is covered with the hydrogen block layer while covering an end surface of the storage element, and

a second protective portion that is linked to the first protective portion, the second protective portion extending away from the storage element in a direction orthogonal to the first direction.

(12)

The semiconductor device according to any one of (8) to (11), in which a first edge of the protective film opposite to the second contact protrudes in the first direction more than a second edge of the storage element opposite to the second contact.

(13)

The semiconductor device according to any one of (8) to (12), in which the hydrogen block layer surrounds a whole of the protective film in the first plane.

The present application claims the priority on the basis of Japanese Patent Application No. 2018-163376 filed on Aug. 31, 2018 with Japan Patent Office, the entire contents of which are incorporated in the present application by reference.

It should be understood by those skilled in the art that various modifications, combinations, sub-combinations, and alterations may occur depending on design requirements and other factors insofar as they are within the scope of the appended claims or the equivalents thereof.

1. A semiconductor device comprising:
a storage element;
a first contact that is electrically coupled to the storage element;
a second contact that is positioned on an opposite side to the first contact in a first direction, the second contact being electrically coupled to the storage element;
a protective film that surrounds the storage element in a first plane orthogonal to the first direction; and
a first hydrogen block layer that surrounds the protective film in the first plane.

2. The semiconductor device according to claim 1, wherein the protective film is provided between a position of a first edge of the first hydrogen block layer and a position of a second edge of the first hydrogen block layer in the first direction.

3. The semiconductor device according to claim 1, further comprising a second hydrogen block layer that covers the first contact, wherein
the first hydrogen block layer and the second hydrogen block layer are linked.

4. The semiconductor device according to claim 3, wherein the first contact includes a portion having an outer diameter greater than an outer diameter of the protective film in the first plane.

5. The semiconductor device according to claim 1, wherein
the first hydrogen block layer and the second contact are coupled, and
the protective film is continuously covered with the first hydrogen block layer and the second contact.

6. The semiconductor device according to claim 5, wherein a dimension of an outer edge of a portion of the second contact opposed to the protective film and the storage element is greater than a dimension of an outer edge of the protective film in the first plane.

7. The semiconductor device according to claim 1, wherein the first hydrogen block layer includes
a first portion that extends in the first direction to cover an outer peripheral surface of the protective film, and
a second portion that is linked to both the first portion and the second contact, the second portion extending away from the storage element in a direction orthogonal to the first direction.

8. A semiconductor device comprising:
a storage element;
a first contact that is electrically coupled to the storage element;
a second contact that is positioned on an opposite side to the first contact in a first direction, the second contact being electrically coupled to the storage element;
a protective film that surrounds the storage element in a first plane orthogonal to the first direction; and
a hydrogen block layer that surrounds at least a portion of the protective film and covers the first contact in the first plane, the hydrogen block layer being insulated from the second contact.

9. The semiconductor device according to claim 8, wherein a dimension of an outer edge of the first contact is greater than a dimension of an outer edge of the protective film in the first plane.

10. The semiconductor device according to claim 8, wherein the hydrogen block layer includes a first boundary portion and a second boundary portion, the first boundary portion separating the first contact and the storage element, the second boundary portion separating the first contact and the protective film and being provided to be continuous to the first boundary portion.

11. The semiconductor device according to claim 8, wherein the protective film includes
a first protective portion that is covered with the hydrogen block layer while covering an end surface of the storage element, and
a second protective portion that is linked to the first protective portion, the second protective portion extending away from the storage element in a direction orthogonal to the first direction.

12. The semiconductor device according to claim 8, wherein a first edge of the protective film opposite to the second contact protrudes in the first direction more than a second edge of the storage element opposite to the second contact.

13. The semiconductor device according to claim 8, wherein the hydrogen block layer surrounds a whole of the protective film in the first plane.
